(19) United States
(12) Patent Application Publication
(10) Pub. No.: US 2011/0198682 A1
(43) Pub. Date: Aug. 18, 2011

(54) NONVOLATILE SEMICONDUCTOR MEMORY DEVICE AND METHOD OF MANUFACTURING THE SAME

(75) Inventor: Kiyomi NARUKE, Sagamihara-shi (JP)

(73) Assignee: KABUSHIKI KAISHA TOSHIBA, Tokyo (JP)

(21) Appl. No.: 12/879,504

(22) Filed: Sep. 10, 2010

(30) Foreign Application Priority Data
Feb. 18, 2010 (JP) 2010-033291

(51) Int. Cl. H01L 29/788; H01L 21/8247

(52) U.S. Cl. 257/324; 438/258; 257/E21.68; 257/E29.3

(57) ABSTRACT

In one embodiment, a nonvolatile semiconductor memory device includes a substrate, and a well of a first conductivity type formed in the substrate. The device further includes a plurality of first isolation layers disposed in parallel to each other in the well, and a second isolation layer disposed in parallel to the first isolation layers in the well, a width of a substrate surface between the second isolation layer and the first isolation layers being set greater than a width of a substrate surface between the first isolation layers. The device further includes a memory cell including a gate insulator, a floating gate, an inter-gate insulator, and a control gate sequentially disposed on the well between the first isolation layers, and a dummy cell including a gate insulator, a floating gate, an inter-gate insulator, and a control gate sequentially disposed on the well between the second isolation layer and one of the first isolation layers. The device further includes a diffusion layer of a second conductivity type formed under the dummy cell in the well between the second isolation layer and the one of the first isolation layers, an upper surface of the diffusion layer being formed at a position higher than bottom surfaces of the first and second isolation layers with the surface of the substrate.

### CROSS REFERENCE TO RELATED APPLICATION

This application is based upon and claims the benefit of priority from the prior Japanese Patent Application No. 2010-33291, filed on Feb. 18, 2010, the entire contents of which are incorporated herein by reference.

### FIELD

Embodiments described herein relate to a nonvolatile semiconductor memory device and a method of manufacturing the same, for example, to a dummy cell provided at an edge of a memory cell array of a NAND flash memory.

### BACKGROUND

In a dummy cell at an edge of a NAND cell array, the width of an active area (AA) is set long from the viewpoint of lithography. Therefore, the dummy cell has a smaller coupling ratio compared to a normal memory cell, and an electric potential Vfg of a floating gate of the dummy cell hardly increases during writing. This expands the potential difference between an electric potential Vcg applied to a word line and the electric potential Vfg of the floating gate in the dummy cell, and therefore a high electric field is applied to an inter-gate insulator (inter-poly dielectric (IPD)) of the dummy cell. It sometimes leads to a dielectric breakdown of the inter-gate insulator. This finally results in a short circuit between the word line and the active area leading to a critical dielectric breakdown.

JP-A 2008-60421 (KOKAI) discloses an example of a nonvolatile semiconductor memory in which source and drain diffusion layers are not formed in a substrate under a dummy cell. In the memory, the channel of the dummy cell is in a state of a depletion layer, which makes it possible to reduce a dielectric breakdown in an inter-gate insulator and a gate insulator of the dummy cell. However, in the memory, the coupling ratio of the dummy cell is small, and therefore the dielectric breakdown of the inter-gate insulator and the gate insulator of the dummy cell sometimes cannot be sufficiently prevented.

### BRIEF DESCRIPTION OF THE DRAWINGS

FIG. 1 is a plan view illustrating a configuration of a nonvolatile semiconductor memory device of a first embodiment;

FIG. 2 is a side sectional view illustrating the configuration of the nonvolatile semiconductor memory device of the first embodiment;

FIG. 3 is a side sectional view illustrating a configuration of a NAND string of the first embodiment;

FIG. 4 is a side sectional view illustrating a configuration of a dummy NAND string of the first embodiment;

FIG. 5 is a circuit diagram illustrating an equivalent circuit of a dummy cell of the first embodiment;

FIG. 6 shows a plan view and side sectional views illustrating a configuration of a depression-type peripheral transistor of the first embodiment;

FIGS. 7 and 8 show side sectional views illustrating a method of manufacturing the nonvolatile semiconductor memory device of the first embodiment;

FIGS. 9 and 10 show plan views for explaining first and second examples of a method of forming n-type diffusion layers of the first embodiment;

FIG. 11 is a plan view illustrating a configuration of a nonvolatile semiconductor memory device of a second embodiment;

FIG. 12 is a side sectional view illustrating a configuration of a dummy NAND string of the second embodiment; and

FIG. 13 is a plan view illustrating a configuration of a nonvolatile semiconductor memory device of a third embodiment.

### DETAILED DESCRIPTION

Embodiments will now be explained with reference to the accompanying drawings.

An embodiment described herein is, for example, a nonvolatile semiconductor memory device including a substrate, and a well of a first conductivity type formed in the substrate. The device further includes a plurality of first isolation layers disposed in parallel to each other in the well, and a second isolation layer disposed in parallel to the first isolation layers in the well, a width of a substrate surface between the second isolation layer and the first isolation layers being set greater than a width of a substrate surface between the first isolation layers. The device further includes a memory cell including a gate insulator, a floating gate, an inter-gate insulator, and a control gate sequentially disposed on the well between the first isolation layers, and a dummy cell including a gate insulator, a floating gate, an inter-gate insulator, and a control gate sequentially disposed on the well between the second isolation layer and one of the first isolation layers. The device further includes a diffusion layer of a second conductivity type formed under the dummy cell in the well between the second isolation layer and the one of the first isolation layers, an upper surface of the diffusion layer being formed at a position higher than bottom surfaces of the first and second isolation layers with the surface of the substrate.

Another embodiment described herein is, for example, a method of manufacturing a nonvolatile semiconductor memory device, the method including forming a well of a first conductivity type in a substrate, and forming a diffusion layer of a second conductivity type in the well. The method further includes forming a first insulating layer and a first electrode layer on the well. The method further includes forming a plurality of first isolation layers penetrating the first electrode layer and the first insulating layer in a side portion of the diffusion layer, the first isolation layers being formed in parallel to each other to have bottom surfaces formed at positions lower than an upper face of the diffusion layer, and forming a second isolation layer penetrating the first electrode layer and the first insulating layer, the second isolation layer being formed in parallel to the first isolation layers at a position where the diffusion layer is sandwiched between the second isolation layer and the first isolation layers, a width of a substrate surface between the second isolation layer and the first isolation layers being set greater than a width of a substrate surface between the first isolation layers. The method further includes forming a second insulating layer and a second electrode layer on the first electrode layer and the first and second isolation layers. The method further includes processing a memory cell on the well between the first isolation layers, the memory cell including the first insulating layer, the first electrode layer, the second insulating layer, and the second electrode layer in sequence, and processing a dummy cell on the well between the second isolation layer and the first isolation layers, the dummy cell including the first insulating layer, the first electrode layer, the second insulating layer, and the second electrode layer in sequence.

### FIRST EMBODIMENT

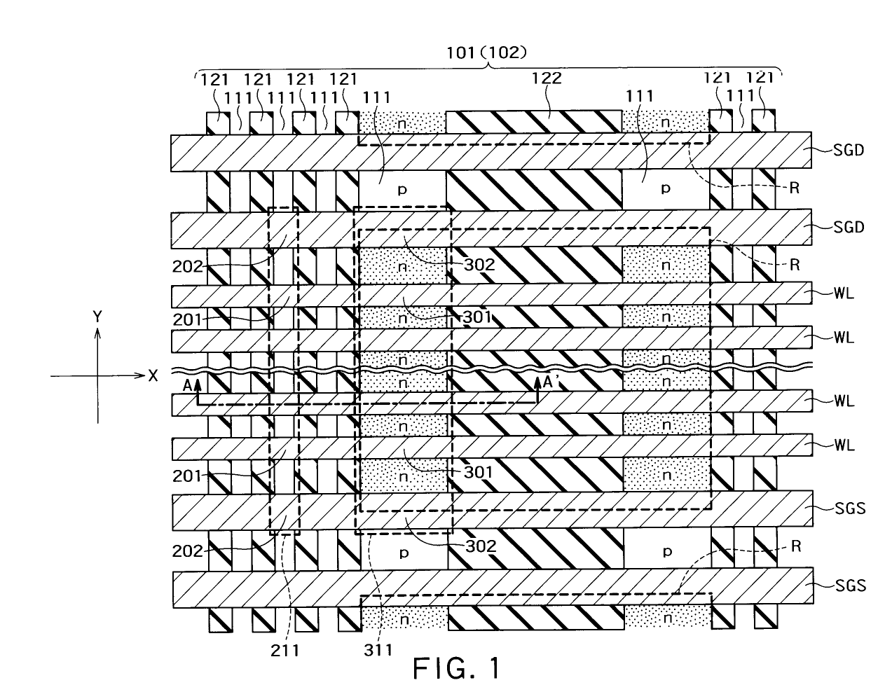

FIG. 1 is a plan view illustrating a configuration of a nonvolatile semiconductor memory device of a first embodiment. FIG. 1 schematically illustrates a configuration of a memory cell array of the nonvolatile semiconductor memory device. The nonvolatile semiconductor memory device in FIG. 1 is a NAND flash memory.

FIG. 1 illustrates a p-type well 102 formed in a substrate 101, and first and second isolation layers 121 and 122 which separate the p-type well 102 into plural device regions 111. An n-type well may be sandwiched between the substrate 101 and the p-type well 102.

The first isolation layers 121 are provided in parallel to one another in the p-type well 102, and the second isolation layer 122 is provided in the p-type well 102 in parallel to the first isolation layers 121. The substrate 101 is a semiconductor substrate, such as a silicon substrate, and the first and second isolation layers 121 and 122 are insulating layers, such as silicon oxides.

FIG. 1 further illustrates X and Y directions which are parallel to the surface of the substrate 101, and are perpendicular to each other.

The X direction is perpendicular to the first and second isolation layers 121 and 122, and the Y direction is parallel to the first and second isolation layers 121 and 122. The first and second isolation layers 121 and 122 have planar shapes extending in the Y direction, and are adjacent to one another in the X direction as illustrated in FIG. 1. FIG. 1 further illustrates word lines WL, select gates SGS for source terminals, and select gates SGD for drain terminals, which are formed on the substrate 101 and extend in the X direction.

In FIG. 1, regions on the first and second isolation layers 121 and 122 correspond to STI (Shallow Trench Isolation) regions. On the other hand, regions between the first isolation layers 121 and regions between the second isolation layer 122 and the first isolation layers 121 correspond to AA (Active Area) regions, which are the above-mentioned device regions 111.

The semiconductor memory device of FIG. 1 includes memory cells (cell transistors) 201 and select transistors 202 formed on the device regions 111 between the first isolation layers 121.

The memory cells 201 are provided at intersections between the word lines WL and the device regions 111, and the select transistors 202 are formed at intersections between the select gates SGS and SGD and the device regions 111. A NAND string 211 includes a plurality of memory cells 201 arranged along the Y direction, and two select transistors 202 provided to sandwich the memory cells 201. The NAND string 211 is an example of a first string of the disclosure. In the semiconductor memory device of FIG. 1, plural NAND strings 211 are arranged at predetermined intervals in the X and Y directions.

Further, the semiconductor memory device of FIG. 1 includes dummy cells (dummy cell transistors) 301 and dummy select transistors 302 provided on the device regions 111 between the second isolation layer 122 and the first isolation layers 121. The dummy cells 301 and the dummy select transistors 302 are dummies of the memory cells 201 and the select transistors 202, respectively.

The dummy cells 301 are provided at intersections between the word lines WL and the device regions 111, and the dummy select transistors 302 are provided at intersections between the select gates SGS and SGD and the device regions 111. A dummy NAND string 311 includes a plurality of dummy cells 301 arranged along the Y direction, and two dummy select transistors 302 formed to sandwich the dummy cells 301. The dummy NAND string 311 is an example of a second string of the disclosure. In the semiconductor memory device of FIG. 1, plural dummy NAND strings 311 are arranged at predetermined intervals in the Y direction.

In the present embodiment, from the viewpoint of lithography, the X-directional width (AA width) of the device region 111 between the first isolation layer 121 and the second isolation layer 122 is set greater than the X-directional width (AA width) of the device region 111 between the first isolation layers 121. In other words, the AA width in an edge part of the memory cell array is set greater than the AA width in other parts. As a result, in the embodiment, the X-directional width of each dummy cell 301 is greater than the X-directional width of each memory cell 201.

FIG. 1 further illustrates a region R which covers the STI region on the second isolation layer 122 and the AA regions between the second isolation layer 122 and the first isolation layers 121, and which is separated between adjacent select gates (i.e., between SGSs and between SGDs).

In the device regions 111 in FIG. 1, an n-type diffusion layer 103 to be described later is formed on the surface of the p-type well 102 in the region R, and the n-type diffusion layer 103 is not formed on the surface of the p-type well 102 outside the region R. That is, the n-type diffusion layer 103 is not formed in channel regions of the memory cells 201 (substrate surface located under the memory cells 201), so that the memory cells 201 are formed directly on the p-type well 102. On the other hand, the n-type diffusion layer 103 is formed in channel regions of the dummy cells 301 (substrate surface located under the memory cells 301), so that the dummy cells 301 are provided on the p-type well 102 via the n-type diffusion layer 103. Note that p-type impurity regions may be formed in the channel regions of the memory cells 201. The p-type well 102 is an example of a well of a first conductivity type of the disclosure, and the n-type diffusion layer 103 is an example of a diffusion layer of a second conductivity type of the disclosure. Details of the region R will be described later.

In FIG. 1, the X and Y directions a channel width direction and a gate length direction of the memory cells 201, the select transistors 202, the dummy cells 301, and the dummy select transistors 302, respectively.

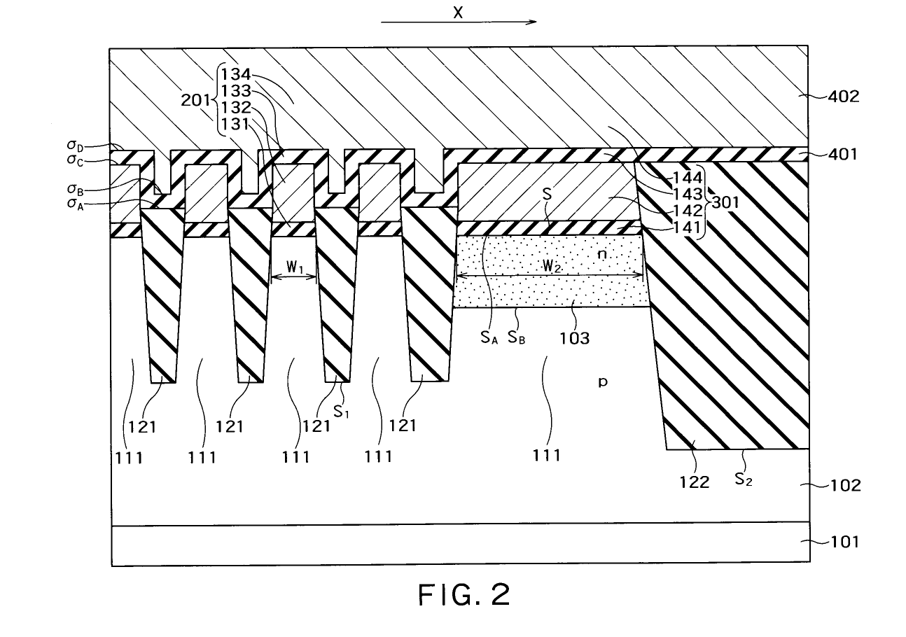

FIG. 2 is a side sectional view illustrating the configuration of the nonvolatile semiconductor memory device of the first embodiment. FIG. 2 is the side sectional view taken along a line A-A′ in FIG. 1.

FIG. 2 illustrates, similarly to FIG. 1, the substrate 101, the p-type well 102 formed in the substrate 101, and the first and second isolation layers 121 and 122 formed in the p-type well 102.

In FIG. 2, the bottom surfaces of the first isolation layers 121 are denoted by S₁, and the bottom surface of the second isolation layer 122 is denoted by S₂. In the embodiment, the bottom surface S₂ of the second isolation layer 122 is formed at a position lower than the bottom surfaces S₁ of the first isolation layers 121, so that the depth of the bottom surface S₂ is greater than that of the bottom surfaces S₁ with a top surface of the substrate 101.

In FIG. 2, the width of the substrate surface between the first isolation layers 121 is denoted by W₁, and the width of the substrate surface between the second isolation layer 122 and its adjacent first isolation layer 121 is denoted by W₂. The width W₁ corresponds to the AA width between the first isolation layers 121, and the width W₂ corresponds to the AA width between the second isolation layer 122 and its adjacent first isolation layer 121. In the embodiment, from the viewpoint of lithography, the width W₂ is set greater than the width W₁.

FIG. 2 further illustrates the memory cells 201 provided on the device regions 111 between the first isolation layers 121. Each of the memory cells 201 includes a gate insulator 131, a floating gate 132, an inter-gate insulator 133, and a control gate 134 which are provided sequentially on a device region 111. The gate insulator 131 is also referred to as “tunnel insulator”, and the inter-gate insulator 133 is also referred to as “inter-poly dielectric (IPD)”.

FIG. 2 further illustrates the dummy cell 301 provided on the device region 111 between the second isolation layer 122 and the first isolation layer 121. Similarly to the memory cells 201, the dummy cell 301 includes a gate insulator 141, a floating gate 142, an inter-gate insulator 143, and a control gate 144 which are provided sequentially on the device region 111.

As illustrated in FIG. 2, the gate insulators and the floating gates included in the memory and dummy cells 201 and 301 arranged along the X direction are separated between the memory and dummy cells 201 and 301 by the first and second isolation layers 121 and 122. In contrast, the memory and dummy cells 201 and 301 arranged along the X direction share the same inter-gate insulator and control gate, and the inter-gate insulator and control gate are provided to extend over the top surfaces of the floating gates 132 and 142 of the memory and dummy cells 201 and 301 and the side surfaces of the upper portions of the floating gates 132 and 142 of the memory and dummy cells 201 and 301. In FIG. 2, the shared inter-gate insulator and control gate are denoted by numerals 401 and 402, respectively. The control gate is illustrated as the word line WL in FIG. 1.

As illustrated in FIG. 2, the inter-gate insulator 401 and the control gate 402 are lowered between the memory cells 201 and between the dummy cell 301 and the memory cells 201. In other words, bottom surfaces σ_{A} of the inter-gate insulator 401 on the first isolation layers 121 are lower than bottom surfaces σ_{C} of the inter-gate insulator 401 between the first isolation layers 121, and bottom surfaces σ_{B} of the control gate 402 on the first isolation layers 121 are lower than bottom surfaces σ_{D} of the control gate 402 between the first isolation layers 121. This has the effect of increasing the capacitance of each memory cell 201.

FIG. 2 further illustrates the n-type diffusion layer 103 formed in an upper portion of the device region 111 between the second isolation layer 122 and the first isolation layer 121. The structure of the n-type diffusion layer 103 is described in detail below.

The n-type diffusion layer 103 is formed under the dummy cell 301 in the channel region of the device region 111 (p-type well 102) between the second isolation layer 122 and the first isolation layer 121. As a result, a pn junction of the p-type well 102 and the n-type diffusion layer 103 is formed in the channel region of the dummy cell 301. In the embodiment, the impurity concentration in the n-type diffusion layer 103 is set, for example, in the range of 1.0×10¹² [cm⁻²] to 1.0×10¹³ [cm⁻²], and, for example, arsenic (As) or phosphorus (P) is employed as the impurity.

In FIG. 2, the upper face of the n-type diffusion layer 103 is denoted by S_{A}, and the lower face of the n-type diffusion layer 103 is denoted by S_{B}. Further, the surface of the substrate 101 between the second isolation layer 122 and the first isolation layer 121 is denoted by S.

In the embodiment, the upper face S_{A} of the n-type diffusion layer 103 is formed higher than the bottom surfaces S₁ and S₂ of the first and second isolation layers 121 and 122 with the surface of the substrate 101. More specifically, the upper face S_{A} of the n-type diffusion layer 103 coincides with the surface S of the substrate 101. Likewise, the lower face S_{B} of the n-type diffusion layer 103 is formed higher than the bottom surfaces S₁ and S₂ of the first and second isolation layers 121 and 122 with the surface of the substrate 101. As a result, in the embodiment, one pn junction plane of the p-type well 102 and the n-type diffusion layer 103 is formed between the second isolation layer 122 and the first isolation layer 121.

As described later, the n-type diffusion layer 103 is formed by forming the n-type diffusion layer 103 in the p-type well 102 before the first and second isolation layers 121 and 122 are formed. The n-type diffusion layer 103 is formed by forming an n-type layer by ion implantation into the region R shown in FIG. 1.

Accordingly, the n-type diffusion layer 103 is continuously formed in the channel regions of the dummy cells 301 included in the same dummy NAND string 311 and between these dummy cells 301, as illustrated in FIG. 1. The region R contains two dummy NAND strings 311 sandwiching the second isolation layer 122. As a result, the n-type diffusion layer 103 can be formed in a wide range as compared with the case of forming the n-type diffusion layer 103 for each dummy cell 301, and therefore this makes it easier to form the n-type diffusion layer 103.

As illustrated in FIG. 1, the n-type diffusion layer 103 is formed to be separated between the dummy NAND strings 311 adjacent in the Y direction. This has the advantage that the capacitance of the pn junction is smaller than that in the case where the n-type diffusion layer 103 is formed to extend over the dummy NAND strings 311 adjacent in the Y direction (if the amount of electrons of the impurity of the n-type diffusion layer 103 becomes excessively large, the same state as the absence of the capacitance Cdep (pn junction of the n-type diffusion layer 103 and the p-type well 102) occurs). As illustrated in FIG. 1, the n-type diffusion layer 103 is not formed in the substrate 101 between the dummy NAND strings 311 adjacent in the Y direction. As a result, the p-type well 102 is formed on the surfaces of the substrate 101 between the select gates SGS and between the select gates SGD. Since the dummy NAND strings 311 adjacent in the Y direction only must be separated by the p-type well 102, the boundary of the region R may exist between the select gates SGS or between the select gates SGD. In other words, the p-type well 102 may exist at least between the select gates SGS and between the select gates SGD to separate the n-type diffusion layer 103 in the Y direction.

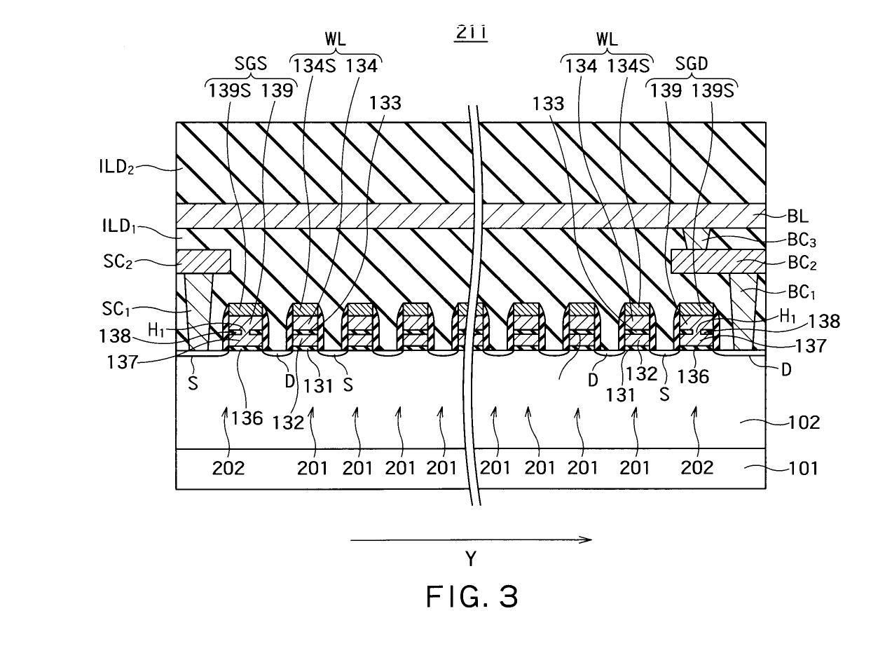

FIG. 3 is a side sectional view illustrating a configuration of the NAND string 211 in FIG. 1. FIG. 3 is the sectional view along the Y direction.

As illustrated in FIG. 3, each memory cell 201 has a stacked structure including the gate insulator 131, the floating gate 132, the inter-gate insulator 133, and the control gate 134 which are sequentially provided on the p-type well 102. A silicide layer 134S is, provided in an upper portion of the control gate 134. Each memory cell 201 forms a memory cell transistor in which electrical characteristics charges are stored in the floating gate 132, thereby altering a threshold voltage. The floating gate 132 is electrically separated for each memory cell 201, whereas the control gate 134 is commonly electrically connected to the memory cells 201 in the word line direction (see FIG. 2).

Each memory cell 201 also includes spacers 135 formed on sidewall surfaces of the stacked structure, and a source diffusion layer S and a drain diffusion layer D which are formed in the p-type well 102 so as to sandwich the stacked structure.

As illustrated in FIG. 3, each select transistor 202 has a stacked structure including a first insulating layer 136, a first electrode layer 137, a second insulating layer 138, and a second electrode layer 139 sequentially provided on the p-type well 102. A silicide layer 139S is provided in an upper portion of the second electrode layer 139. The first electrode layer 137 and the second electrode layer 139 are made electrically conducting with an opening H₁ formed in the second insulating layer 138. The first insulating layer 136 is called a gate insulator, and the first and second electrode layers 137 and 139 are called a gate electrode.

Each select transistor 202 also includes spacers 140 provided on sidewall surfaces of the stacked structure, and a source diffusion layer S and a drain diffusion layer D which are formed in the p-type well 102 so as to sandwich the stacked structure.

FIG. 3 illustrates a bit line BL provided above the NAND string 211. Two select transistors 202 of each NAND string 211 are used for selecting the NAND string 211 and connecting it to the bit line BL. The gate electrode of one select transistor 202 is connected to the select gate SGS, and the gate electrode of the other select transistor 202 is connected to the select gate SGD.

FIG. 3 further illustrates source line contacts SC₁ and SC₂ which are sequentially formed on the source diffusion layer S of one select transistor 202, and bit line contacts BC₁, BC₂ and BC₃ which are sequentially formed on the drain diffusion layer D of the other select transistor 202. The source line contacts SC₁ and SC₂ are electrically connected to a source line (not illustrated), and the bit line contacts BC₁, BC₂ and BC₃ are electrically connected to the bit line BL.

FIG. 3 further illustrates first and second inter layer dielectrics ILD₁ and ILD₂ which are sequentially formed on the substrate 101. The first inter layer dielectric ILD₁ is formed on the substrate 101 so as to cover the NAND string 211. The source line contacts SC₁ and SC₂ and the bit line contacts BC₁, BC₂ and BC₃ are buried in the first inter layer dielectric ILD₁, and the bit line BL is formed on the first inter layer dielectric ILD₁. The second inter layer dielectric ILD₂ is formed on the first inter layer dielectric ILD₁ so as to cover the bit line BL.

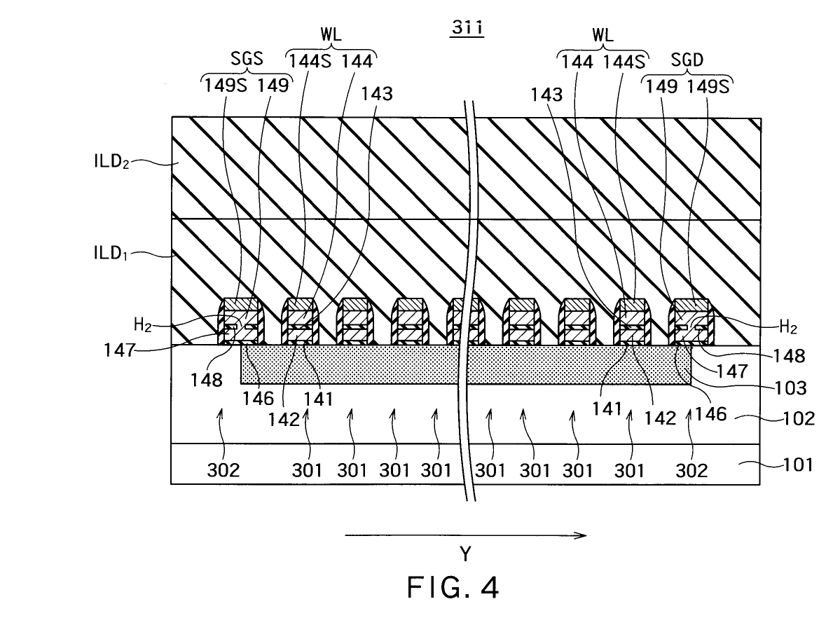

FIG. 4 is a side sectional view illustrating a configuration of the dummy NAND string 311 in FIG. 1. FIG. 4 is the sectional view along the Y direction.

As illustrated in FIG. 4, the sectional structure of the dummy NAND string 311 is approximately the same as that of the NAND string 211. The dummy NAND string 311 is different from the NAND string 211 in that the n-type diffusion layer 103 is formed, and that the source line contacts SC₁ and SC₂, the bit line contacts BC₁, BC₂ and BC₃, and the bit line BL are not formed.

As illustrated in FIG. 4, each dummy cell 301 has a stacked structure including the gate insulator 141, the floating gate 142, the inter-gate insulator 143, and the control gate 144 which are provided sequentially on the n-type diffusion layer 103. A silicide layer 144S is provided in an upper portion of the control gate 144. The floating gate 142 is electrically separated from the memory cells 201 in the word line direction, whereas the control gate 144 is commonly electrically connected to the memory cells 201 in the word line direction (see FIG. 2).

Each dummy cell 301 also includes spacers 145 provided on sidewall surfaces of the stacked structure.

As illustrated in FIG. 4, each dummy select transistor 302 has a stacked structure including a first insulating layer 146, a first electrode layer 147, a second insulating layer 148, and a second electrode layer 149 sequentially provided on the p-type well 102 and the n-type diffusion layer 103. A silicide layer 149S is provided in an upper portion of the second electrode layer 149. The first electrode layer 147 and the second electrode layer 149 are made electrically conducting with an opening H₂ formed in the second insulating layer 148. The first insulating layer 146 is called a gate insulator, and the first and second electrode layers 147 and 149 are called a gate electrode.

Each dummy select transistor 302 also includes spacers 150 provided on sidewall surfaces of the above-mentioned stacked structure.

As illustrated in FIG. 4, the n-type diffusion layer 103 is continuously formed in channel regions of the dummy cells 301, between the dummy cells 301, and between the dummy cells 301 and the dummy select transistors 302. Ends of the n-type diffusion layer 103 are positioned approximately at the centers of the channel regions of the dummy select transistors 302 in the Y direction.

Each dummy cell 301 may include source and drain diffusion layers formed in the n-type diffusion layer 103 so as to sandwich the stacked structure.

Further, source and drain diffusion layers formed in the p-type well 102 and the n-type diffusion layer 103 may be provided between each dummy select transistor 302 and its adjacent dummy cell 301. In FIG. 4, source and drain diffusion layers for each dummy select transistor 302 are not formed, and the n-type diffusion layers 103 are separated from each other by the p-type well 102 between the dummy NAND strings 311 adjacent in the Y direction.

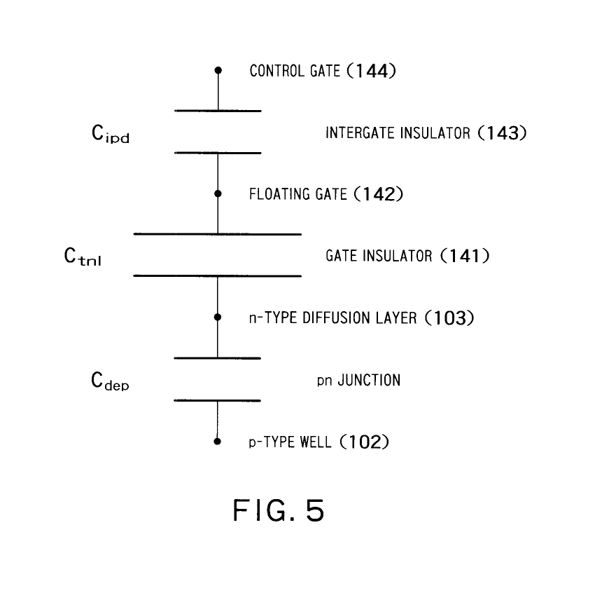

FIG. 5 is a circuit diagram illustrating an equivalent circuit of a dummy cell 301. Referring to FIG. 5, advantages of providing the n-type diffusion layer 103 under the dummy cells 301 are described below.

Characters Cipd and Ctnl shown in FIG. 5 denote capacitances of the inter-gate insulator 143 and the gate insulator 141 included in the dummy cell 301, respectively. Character Cdep shown in FIG. 5 denotes a capacitance of the pn junction of the p-type well 102 and the n-type diffusion layer 103. In the embodiment, the dummy cell 301 has a capacitance obtained by connecting in series the capacitances Cipd, Ctnl, and Cdep as illustrated in FIG. 5.

In the embodiment, by providing the n-type diffusion layer 103 under the dummy cell 301, a depletion layer due to a pn junction is formed in the channel region of the dummy cell 301, and therefore the capacitance Cdep is generated. In the embodiment, this capacitance Cdep reduces the capacitance between the floating gate 142 and the p-type well 102 of the dummy cell 301. During writing of the semiconductor memory device, a voltage is applied to expand the depletion layer.

In the embodiment, this causes the electrical potential of the floating gate 142 to easily increase during writing. As a result, in the embodiment, an electric field applied to the inter-gate insulator 143 during writing is relaxed, and this makes it possible to avoid causing a critical defect in the semiconductor memory device.

In the embodiment, the impurity concentration in the n-type diffusion layer 103 is set, for example, in the range of 1.0×10¹² [cm⁻²] to 1.0×10¹³ [cm⁻²]. If the impurity concentration is below the range, the capacitance Cdep is insufficient, and therefore there is a possibility that an electric field applied to the inter-gate insulator 143 is not sufficiently relaxed. On the other hand, if the impurity concentration is above the range, the amount of electrons of the impurity in the n-type diffusion layer 103 becomes excessively large, and therefore there is a possibility that the same state as the absence of the capacitance Cdep (pn junction of the n-type diffusion layer 103 and the p-type well 102) occurs. In the embodiment, to address these problems, the impurity concentration is set in the range of 1.0×10¹² [cm⁻²] to 1.0×10¹³ [cm⁻²] to achieve sufficient relaxation of an electric field applied to the inter-gate insulator 143.

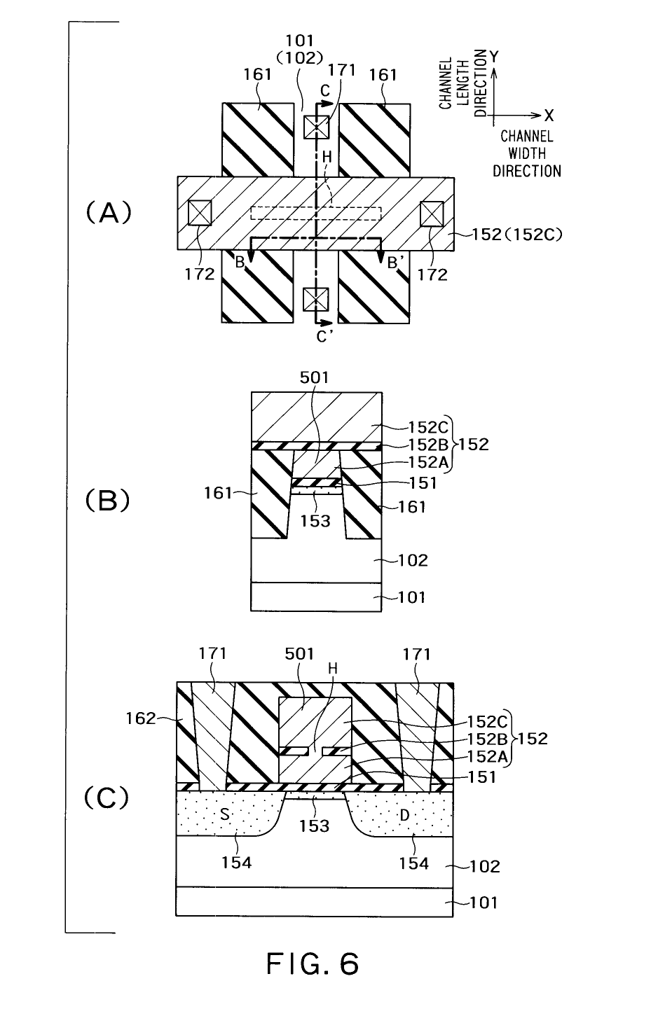

FIG. 6 shows a plan view and side sectional views illustrating a configuration of a depression-type peripheral transistor 501. FIG. 6(A) is a plan view illustrating the configuration of the peripheral transistor 501 which is in the periphery of the memory cell array illustrated in FIG. 1. FIGS. 6(B) and 6(C) are side sectional views taken along the line B-B′ (channel width direction) and the line C-C′ (channel length direction) in FIG. 6(A), respectively. The configuration of the peripheral transistor 501 is described in detail below.

As illustrated in FIG. 6(A), a plurality of isolation layers 161 extending in the channel length direction is arranged in a peripheral circuit part on the substrate 101, and separates the p-type well 102. Further, a gate electrode 152 extending in the channel width direction is arranged on the p-type well 102 and the isolation layers 161, and intersects the p-type well 102 and the isolation layers 161. As illustrated in FIG. 6(A), a hole H is formed in the gate electrode 152.

In FIG. 6(C), which is the sectional view in the channel length direction, the substrate 101 and the p-type well 102 formed in the substrate 101 are illustrated, similarly to FIG. 2. In FIG. 6(C), the peripheral transistor 501 formed on the p-type well 102 is further illustrated. The peripheral transistor 501 is a depression-type n-channel MOS transistor having an n-type impurity in its channel diffusion layer 153.

As illustrated in FIG. 6(C), the peripheral transistor 501 includes a gate insulator 151 and the gate electrode 152 sequentially provided on the p-type well 102. The gate electrode 152 includes a first electrode layer 152A, an insulating layer 152B, and a second electrode layer 152C sequentially provided on the gate insulator 151. The first electrode layer 152A and the second electrode layer 152C are made conducting with the hole H penetrating the insulating layer 152B.

As illustrated in FIG. 6(C), the peripheral transistor 501 further includes an n-type channel diffusion layer 153 and n-type source and drain diffusion layers 154 formed in the p-type well 102. The channel diffusion layer 153 is formed on the surface of the p-type well 102 and under the gate electrode 152, and the source and drain diffusion layers 154 are formed in the p-type well 102 so as to sandwich the gate electrode 152.

In FIG. 6(B), which is the sectional view in the channel width direction, the plurality of isolation layers 161 which separates the p-type well 102 is illustrated. FIG. 6(B) further illustrates a structure in which the gate insulator 151 and the first electrode layer 152A are provided between the isolation layers 161 on the p-type well 102, and the insulating layer 152B and the second electrode layer 152C are formed on the first electrode layer 152A and the isolation layers 161.

FIG. 6(C) illustrates an inter layer dielectric 162 provided on the substrate 101 so as to cover the peripheral transistor 501, and contact plugs 171 provided on the source and drain diffusion layers 154. FIG. 6(A) illustrates planar shapes of the gate electrode 152 and the isolation layers 161, and arrangements of the contact plugs 171 and 172.

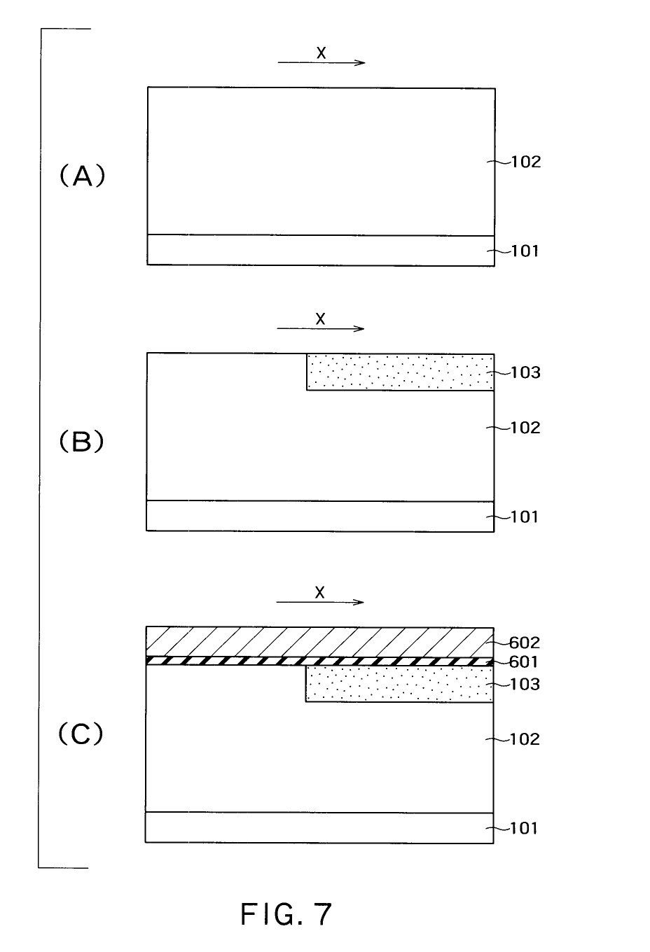

Here, a description is given of the relationship between the n-type diffusion layer 103 illustrated in FIG. 2 and the channel diffusion layer 153 illustrated in FIG. 7.

In the embodiment, the impurity in the n-type diffusion layer 103 is preferably of the same kind as the impurity in the channel diffusion layer 153. The n-type diffusion layer 103 is preferably formed by the same ion implantation process as the channel diffusion layer 153. This makes it possible to form the n-type diffusion layer 103 without increasing the number of processes and, as a result, manufacture costs of the semiconductor memory device can be suppressed. Examples of the impurity include arsenic (As) and phosphorus (P).

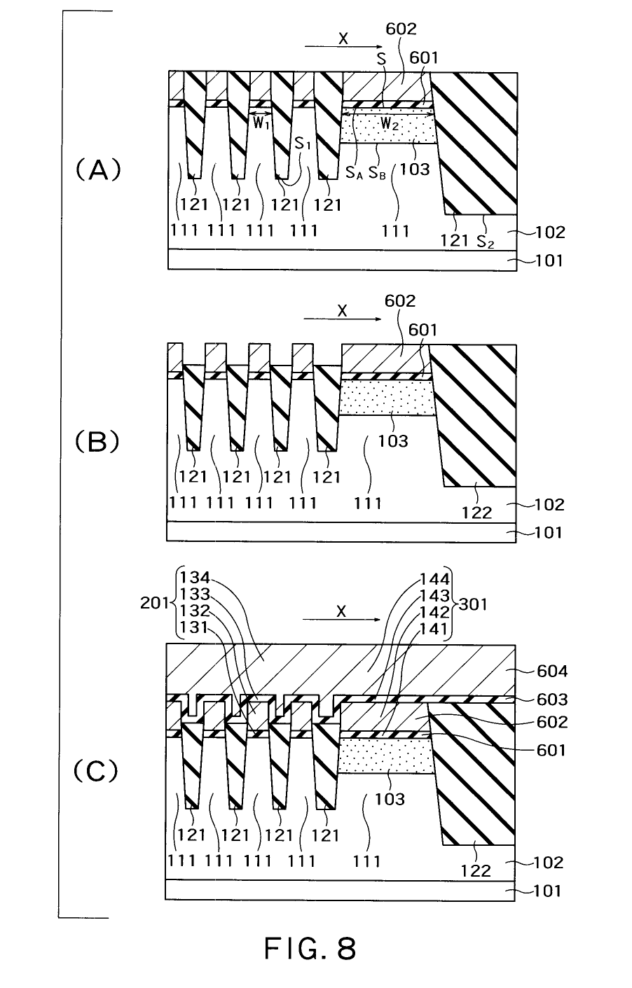

FIGS. 7 and 8 show side sectional views illustrating a method of manufacturing the nonvolatile semiconductor memory device of the first embodiment. Each drawing in FIGS. 7 and 8 is a side sectional view taken along the line A-A′ in FIG. 1. The method of manufacturing the semiconductor memory device of the present embodiment is described below.

As illustrated in FIG. 7(A), the p-type well 102 is formed in the substrate 101. As illustrated in FIG. 7(B), the n-type diffusion layer 103 is formed in the p-type well 102.

The impurity in the n-type diffusion layer 103 is preferably of the same kind as the impurity in the channel diffusion layer 153 (FIG. 6), and the n-type diffusion layer 103 is preferably formed by the same ion implantation process as that of the channel diffusion layer 153.

As illustrated in FIG. 7(C), a first insulating layer 601 is formed on the p-type well 102. The first insulating layer 601 is used as a material for the gate insulators 131 (FIG. 2) of the memory cells 201, the gate insulator 141 (FIG. 2) of the dummy cell 301, the gate insulator 151 (FIG. 6) of the peripheral transistor 501 and the like.

As illustrated in FIG. 7(C), a first electrode layer 602 is formed on the first insulating layer 601. The first electrode layer 602 is used as a material for the floating gates 132 (FIG. 2) of the memory cells 201, the floating gate 142 (FIG. 2) of the dummy cell 301, the first electrode layer 152A (FIG. 6) of the peripheral transistor 501 and the like.

As illustrated in FIG. 8(A), the first and second isolation layers 121 and 122 which penetrate the first electrode layer 602 and the first insulating layer 601 are formed on the p-type well 102. The first isolation layers 121 are formed in a side portion of the n-type diffusion layer 103. Also, the first isolation layers 121 are formed in parallel to one another to have their bottom surfaces S₁ at positions lower than the upper face S_{A} of the n-type diffusion layer 103 with the surface of the substrate 101. The second isolation layer 122 is formed in parallel to the first isolation layers 121 at a position where the n-type diffusion layer 103 is sandwiched between the second isolation layer 122 and the first isolation layers 121. Also, the second isolation layer 122 is formed so that the width W₂ of the substrate surface between the second isolation layer 122 and the first isolation layers 121 is greater than the width W₁ of the substrate surface between the first isolation layers 121. Similarly to the first isolation layers 121, the second isolation layer 122 is formed so as to have its bottom surface S₂ at a position lower than the upper face S_{A} of the n-type diffusion layer 103 with the surface of the substrate 101.

The first and second isolation layers 121 and 122 are formed by forming isolation trenches for these isolation layers in the p-type well 102, burying an insulating layer in the isolation trenches, and planarizing the surface of the insulating layer by chemical mechanical polishing (CMP).

As illustrated in FIG. 8(B), the upper surfaces of the first isolation layers 121 are lowered by etching. FIG. 8(B) illustrates a state in which the upper surfaces of the first isolation layers 121 are lower than the upper surfaces of the second isolation layer 122 and the first electrode layers 602.

As illustrated in FIG. 8(C), a second insulating layer 603 is formed on the first electrode layers 602 and the first and second isolation layers 121 and 122. The second insulating layer 603 is used as a material for the inter-gate insulators 133 (FIG. 2) of the memory cells 201, the inter-gate insulator 143 (FIG. 2) of the dummy cell 301, the insulating layer 152B (FIG. 6) of the peripheral transistor 501 and the like.

As illustrated in FIG. 8(C), a second electrode layer 604 is formed on the second insulating layer 603. The second electrode layer 604 is used as a material for the control gates 134 (FIG. 2) of the memory cells 201, the control gate 144 (FIG. 2) of the dummy cell 301, the second electrode layer 152C (FIG. 6) of the peripheral transistor 501 and the like.

In the embodiment, the second electrode layer 604 is made of a lower layer and an upper layer. The lower layer is formed on the second insulating layer 603, and then the hole H for the peripheral transistor 501 is formed so that the hole H penetrates the lower layer and the second insulating layer 603. Then, the upper layer is formed on the lower layer, thereby forming the second electrode layer 604. Simultaneously with formation of the hole H for the peripheral transistor 501, holes for the select transistor 202 and the dummy select transistor 302 (FIG. 1) are formed. This causes electrode layers of the select transistor 202 to be conducting each other, and causes electrode layers of the dummy select transistor 302 to be conducting each other, similarly to electrode layers of the peripheral transistor 501.

In the embodiment, etching of the second electrode layer 604, the second insulating layer 603, and the first electrode layer 602 is performed. By this etching, the second electrode layer 604 is processed into the forms of the word lines WL illustrated in FIG. 1. In the embodiment, ion implantation for forming the source and drain diffusion layers 154 (FIG. 6) and the like is performed.

In this way, gate processing is performed for forming the memory cells 201, the select transistors 202, the dummy cells 301, the dummy select transistors 302, and the peripheral transistor 501 illustrated in FIGS. 1 to 4 and 6. As a result, the NAND strings 211 and the dummy NAND strings 311 are formed as illustrated in FIGS. 1, 3 and 4. In this way, the semiconductor memory device of the embodiment is manufactured.

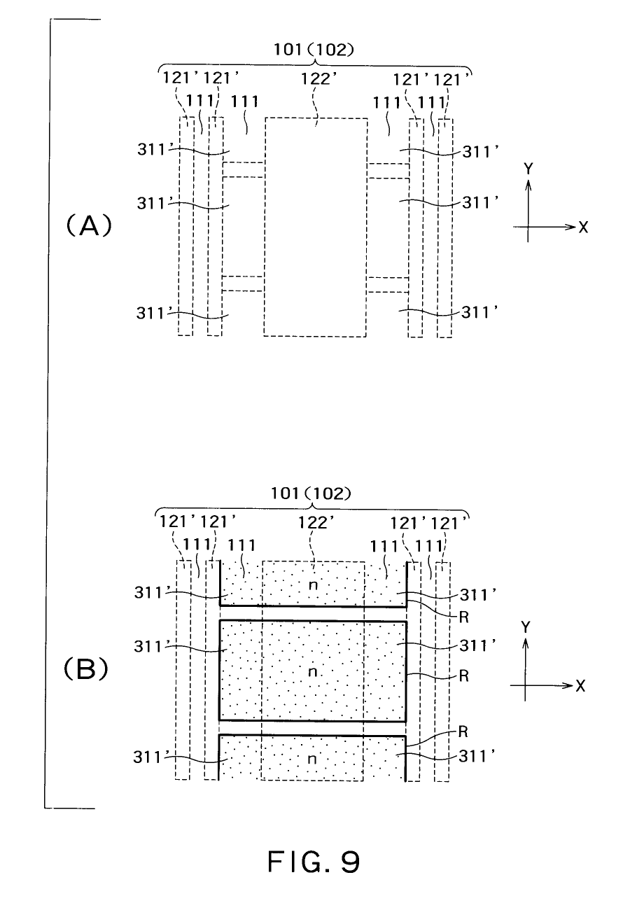

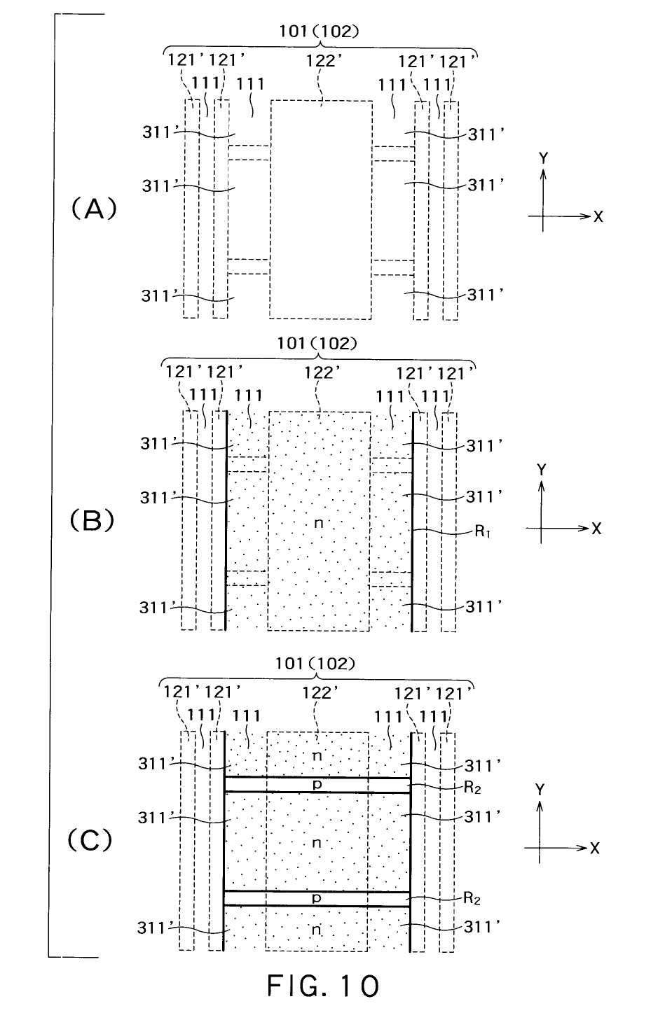

Referring to FIGS. 9 and 10, specific examples of a method of forming n-type diffusion layers 103 are described in detail below.

FIG. 9 shows plan views for explaining a first example of the method of forming the n-type diffusion layers 103.

FIG. 9(A) is a plan view illustrating the substrate 101 after the process illustrated in FIG. 7(A) is performed. FIG. 9(A) illustrates the substrate 101, and the p-type well 102 formed in the substrate 101. In FIG. 9(A), regions where the first isolation layers 121 are to be formed are denoted by 121′, a region where the second isolation layer 122 is to be formed is denoted by 122′, and regions where the dummy NAND strings 311 are to be formed are denoted by 311′.

In the first example, as illustrated in FIG. 9(B), an n-type impurity is implanted into the p-type well 102 in the regions R illustrated in FIG. 1. This causes the regions R to be the n-type diffusion layers 103.

In the first example, as illustrated in FIG. 9(B), the entire regions 311′ where the dummy NAND strings are to be formed are covered with the regions R. Consequently, the n-type impurity is implanted into the entire p-type well 102 in two regions 311′ where the dummy NAND strings are to be formed, which are adjacent in the X direction via the region 122′ where the second isolation layer is to be formed. Therefore, as illustrated in FIG. 1, each of the n-type diffusion layers 103 is formed to extend over the dummy cells 301 included in two dummy NAND strings 311 which are adjacent in the X direction via the second isolation layer 122. This has the advantage of making easier the formation of the n-type diffusion layers 103 as compared to the formation of the n-type diffusion layers 103 for the respective dummy cells 301. The n-type diffusion layers 103 formed in the region 122′ where the second isolation layer is to be formed is removed at the time of forming an isolation trench for the second isolation layer 122. That is, it can be said that the n-type diffusion layers 103 of the dummy NAND strings 311 adjacent in the X direction via the second isolation layer 122 are separated by the second isolation layer 122.

In the first example, as illustrated in FIG. 9(B), the regions R are separated from each other between the regions 311′ where the dummy NAND strings are to be formed, which are adjacent in the Y direction. Therefore, as illustrated in FIG. 1, the n-type diffusion layers 103 are formed to be separated from each other between the dummy NAND strings 311 adjacent in the Y direction. This has the advantage of decreasing the amount of electrons in the n-type diffusion layer 103 of each dummy NAND string 311 as compared to the case where the n-type diffusion layer 103 is formed to extend over the dummy NAND strings 311 adjacent in the Y direction (if the amount of electrons of the impurity of the n-type diffusion layer 103 becomes excessively large, the same state as the absence of the capacitance Cdep (pn junction of the n-type diffusion layer 103 and the p-type well 102) occurs).

Each end of a region R in the X direction may be between the region 122′ where the second isolation layer is to be formed and its adjacent region 121′ where the first isolation layer is to be formed. In this case, the n-type impurity is not implanted into a part of the dummy NAND string 311, which results in exposure of the p-type well 102 in the part. However, if at least the n-type diffusion layer 103 is formed in a part of a region under the floating gate 142 of the dummy cell 301, a depletion layer due to a pn junction is formed in the channel region of the dummy cell 301. This makes it possible to avoid causing a critical defect in the semiconductor memory device.

Each end of the region R in the X direction may be in the above-mentioned region 121′ where the first isolation layer adjacent to the second isolation layer is to be formed. Consequently, in the region R, the n-type impurity is continuously implanted into the p-type well 102 in the region 122′ where the second isolation layer is to be formed, and into a part of the p-type well 102 in the above-mentioned region 121′ where the first isolation layer is to be formed, which is adjacent to the region 311′ where the dummy NAND string is to be formed. This has the advantage that even if the range of implanting the n-type impurity is displaced in the X direction, the n-type diffusion layer 103 is formed under the dummy NAND string 311.

While each region R has a shape covering two dummy NAND strings 311 at both edges of the second isolation layer 122 in the X direction, a shape covering just one dummy NAND string 311 is also acceptable. In other words, the range of implantation of the n-type impurity may be set to extend over a plurality of dummy NAND strings 311, or may be set for the respective dummy NAND strings 311.

FIG. 10 show plan views for explaining a second example of the method of forming the n-type diffusion layers 103.

Similarly to FIG. 9(A), FIG. 10(A) is a plan view illustrating the substrate 101 after performing the process illustrated in FIG. 7(A).

In the second example, as illustrated in FIG. 10(B), an n-type impurity is implanted into the p-type well 102 in a region R₁ obtained by connecting the regions R illustrated in FIG. 1. This causes the region R₁ to be an n-type layer. Further, as illustrated in FIG. 10(C), a p-type impurity is implanted into n-type layers in regions R₂ serving as connecting portions between the regions R. This causes the regions R₂ to be p-type layers. As a result, the regions R obtained by removing the regions R₂ from the region R₁ is the n-type diffusion layers 103.

In this way, in the second example, the n-type impurity is implanted into the p-type well 102 extending over the regions 311′ where the dummy NAND strings are to be formed, which are adjacent in the Y direction (FIG. 10(B)), and then the p-type impurity is implanted into the p-type well 102 between the regions 311′ where the dummy NAND strings are to be formed, which are adjacent in the Y direction (FIG. 10(C)). Consequently, the same n-type diffusion layers 103 as in the first example can be formed.

As described above, in the embodiment, the n-type diffusion layer 103 having the upper face S_{A} at a position higher than the bottom surfaces S₁ and S₂ of the first and second isolation layers 121 and 122 is formed under the dummy cell 301 in the p-type well 102 between the second isolation layer 122 and the first isolation layer 121. Consequently, a depletion layer due to a pn junction is formed in the channel region of the dummy cell 301. This makes it possible to relax an electric field applied to the inter-gate insulator 143 of the dummy cell 301 to avoid causing a critical defect in the semiconductor memory device.

Second and third embodiments described herein are described below. Since these embodiments are modifications of the first embodiment, differences of these embodiments from the first embodiment are mainly described.

### SECOND EMBODIMENT

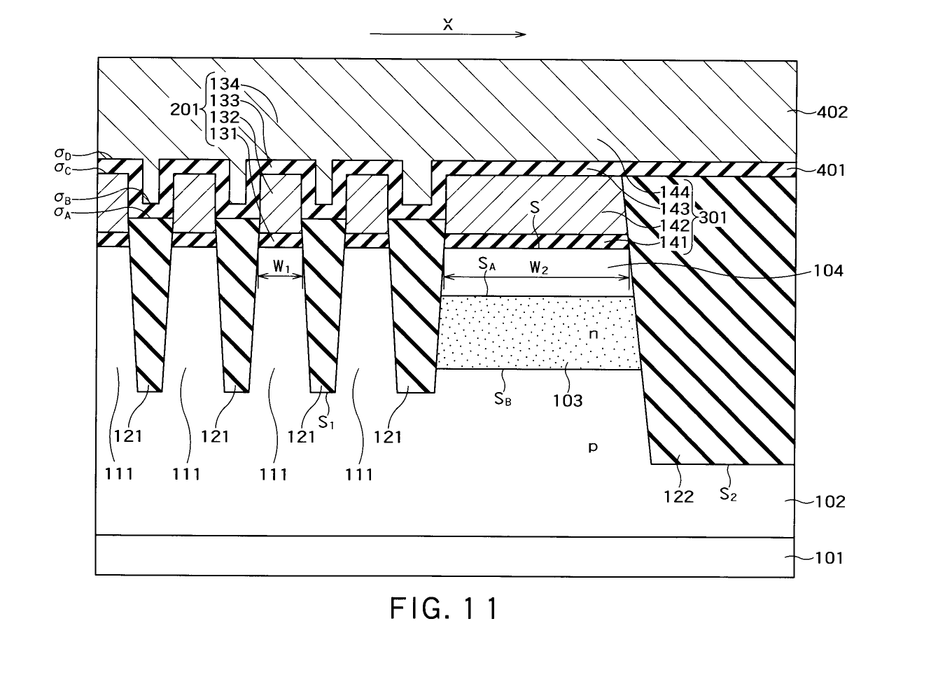

FIG. 11 is a side sectional view illustrating a configuration of a nonvolatile semiconductor memory device of a second embodiment.

In the first embodiment (FIG. 2), the upper face S_{A} of the n-type diffusion layer 103 is formed at a position higher than the bottom surfaces S₁ and S₂ of the first and second isolation layers 121 and 122 with the surface S of the substrate 101. More specifically, the upper face S_{A} of the n-type diffusion layer 103 coincides with the surface S of the substrate 101. Likewise, the lower face S_{B} of the n-type diffusion layer 103 is formed at a position higher than the bottom surfaces S₁ and S₂ of the first and second isolation layers 121 and 122. As a result, in the first embodiment, one pn junction plane of the p-type well 102 and the n-type diffusion layer 103 is formed between the second isolation layer 122 and its adjacent first isolation layer 121.

In contrast, in the second embodiment (FIG. 11), although the upper face S_{A} of the n-type diffusion layer 103 is formed at a position higher than the bottom surfaces S₁ and S₂ of the first and second isolation layers 121 and 122 with the surface S of the substrate 101. On the other hand, the upper face S_{A} is not coincident with the surface S of the substrate 101 and is formed at a position lower than the surface S of the substrate 101. The lower face S_{B} of the n-type diffusion layer 103 is formed at a position higher than the bottom surfaces S₁ and S₂ of the first and second isolation layers 121 and 122, as in the first embodiment. As a result, in the second embodiment, two pn junction planes of the p-type well 102 and the n-type diffusion layer 103 are formed between the second isolation layer 122 and its adjacent first isolation layer 121. In other words, it can be said that a p-type well 104, which is a part of the p-type well 102, is sandwiched between the gate insulator 141 of the dummy cell 301 and the n-type diffusion layer 103.

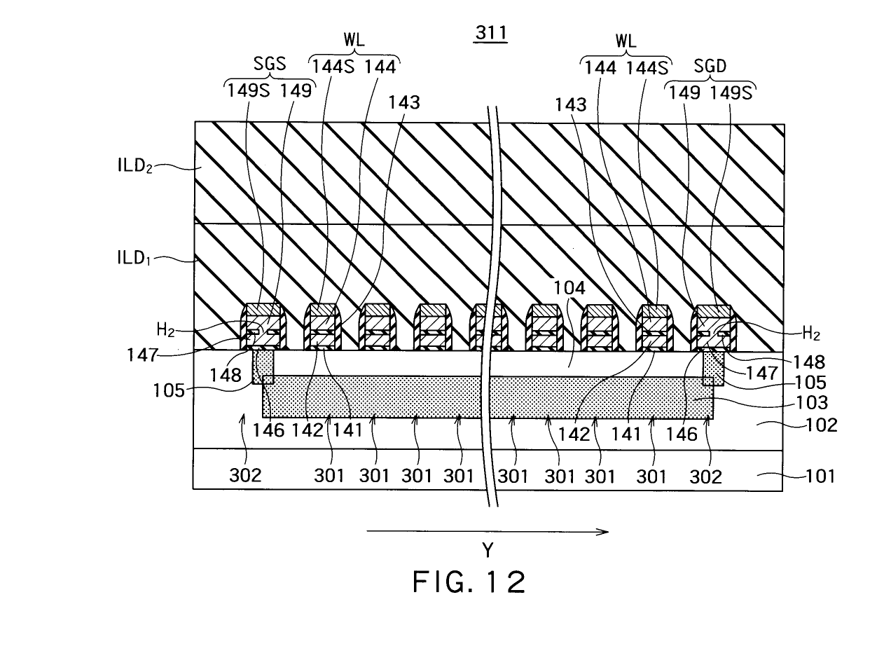

FIG. 12 is a side sectional view illustrating a configuration of the dummy NAND string 311 of the second embodiment.

In the present embodiment, the p-type well 104 is separated from the p-type well 102 by the n-type diffusion layer 103. For this reason, as illustrated in FIG. 12, connection n-type diffusion layers 105 are formed so that the p-type well 104 is surrounded by the n-type diffusion layer 103 and the connection n-type diffusion layers 105 in a cross-section along the Y direction. The connection n-type diffusion layers 105 are formed in the vicinity of the regions under two dummy select transistors 302 included in the dummy NAND string 311 so that the upper faces of the connection n-type diffusion layers 105 are in contact with the gate insulators 141 and the lower faces of the connection n-type diffusion layers 105 overlap upper portions of the n-type diffusion layer 103. In other words, the connection n-type diffusion layers 105 are arranged so as to sandwich the p-type well 104 in a cross-section along the Y direction.

In this way, in the second embodiment, the pn junctions of the p-type well 102 and the n-type diffusion layer 103 is formed between the second isolation layer 122 and the first isolation layer 121, as in the first embodiment. Consequently, depletion layers due to the pn junctions are formed in the channel region of the dummy cell 301 in the second embodiment. This makes it possible to relax an electric field applied to the inter-gate insulator 143 of the dummy cell 301 to avoid causing a critical defect in the semiconductor memory device, similarly to the first embodiment.

### THIRD EMBODIMENT

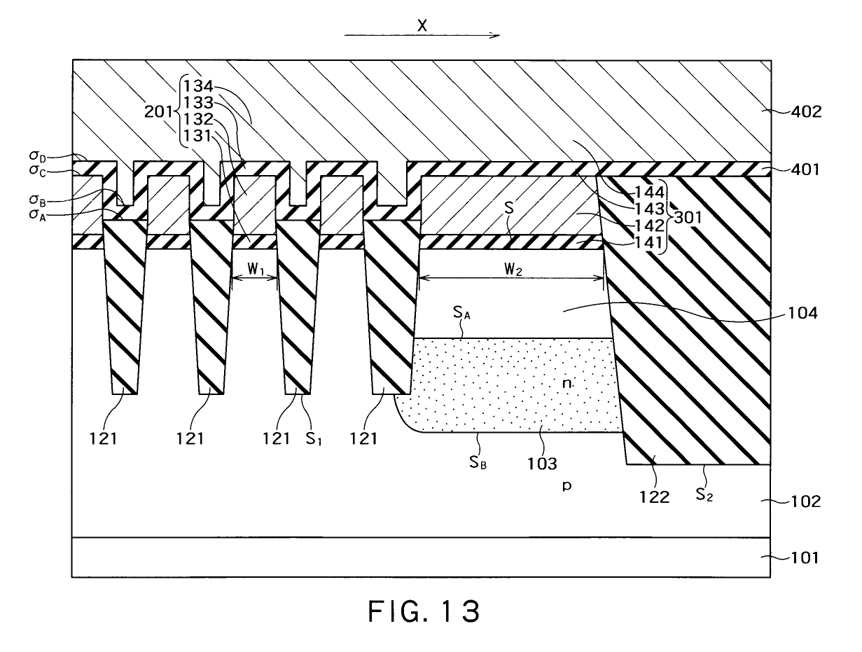

FIG. 13 is a side sectional view illustrating a configuration of a nonvolatile semiconductor memory device of a third embodiment.

In the second embodiment (FIG. 11), the upper face S_{A} of the n-type diffusion layer 103 is formed at a position higher than the bottom surfaces S₁ and S₂ of the first and second isolation layers 121 and 122 and lower than the surface S of the substrate 101. The lower face S_{B} of the n-type diffusion layer 103 is formed at a position higher than the bottom surfaces S₁ and S₂ of the first and second isolation layers 121 and 122 with the surface S of the substrate 101. As a result, in the second embodiment, two pn junction planes of the p-type well 102 and the n-type diffusion layer 103 are formed in the substrate 101 under the dummy cell 301.

On the other hand, in the third embodiment (FIG. 13), the upper face S_{A} of the n-type diffusion layer 103 is formed at a position higher than the bottom surfaces S₁ and S₂ of the first and second isolation layers 121 and 122 and lower than the surface S of the substrate 101, as in the second embodiment. However, the lower face S_{B} of the n-type diffusion layer 103 is formed at a position lower than the bottom surfaces S₁ of the first isolation layers 121 and higher than the bottom surface S₂ of the second isolation layer 122 with the surface S of the substrate 101. As a result, in the third embodiment, two pn junction planes of the p-type well 102 and the n-type diffusion layer 103 are formed in the substrate 101 under the dummy cell 301.

In the present embodiment, similarly to the second embodiment, the p-type well 104 is separated from the p-type well 102 by the n-type diffusion layer 103. Therefore, as illustrated in FIG. 12, the connection n-type diffusion layers 105 are formed so that the p-type well 104 is surrounded by the n-type diffusion layer 103 and the connection n-type diffusion layers 105 in a cross-section along the Y direction.

In this way, in the third embodiment, the pn junctions of the p-type well 102 and the n-type diffusion layer 103 is formed in the substrate 101 under the dummy cell 301, as in the first and second embodiments. Consequently, depletion layers due to the pn junctions are formed in the channel region of the dummy cell 301, in the third embodiment. This makes it possible to relax an electric field applied to the inter-gate insulator 143 of the dummy cell 301 to avoid causing a critical defect in the semiconductor memory device, similarly to the first and second embodiments.

As described above, according to the embodiments described herein, it is possible to provide a nonvolatile semiconductor memory device and a method of manufacturing the same, which can relax an electric field applied to an inter-gate insulator of a dummy cell to avoid causing a critical defect in the device.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

1. A nonvolatile semiconductor memory device comprising:
a substrate;
a well of a first conductivity type formed in the substrate;
a plurality of first isolation layers disposed in parallel to each other in the well;
a second isolation layer disposed in parallel to the first isolation layers in the well, a width of a substrate surface between the second isolation layer and the first isolation layers being set greater than a width of a substrate surface between the first isolation layers;
a memory cell including a gate insulator, a floating gate, an inter-gate insulator, and a control gate sequentially disposed on the well between the first isolation layers;
a dummy cell including a gate insulator, a floating gate, an inter-gate insulator, and a control gate sequentially disposed on the well between the second isolation layer and one of the first isolation layers; and
a diffusion layer of a second conductivity type formed under the dummy cell in the well between the second isolation layer and the one of the first isolation layers, an upper surface of the diffusion layer being formed at a position higher than bottom surfaces of the first and second isolation layers with the surface of the substrate.

2. The device according to claim 1, wherein
the upper face of the diffusion layer is coincident with the surface of the substrate.

3. The device according to claim 1, wherein
the upper face of the diffusion layer is formed at a position lower than the surface of the substrate.

4. The device according to claim 1, wherein
a lower face of the diffusion layer is formed at a position higher than the bottom surfaces of the first and second isolation layers with the surface of the substrate.

5. The device according to claim 1, wherein
a lower surface of the diffusion layer is formed at a position lower than the bottom surfaces of the first isolation layers and higher than the bottom surface of the second isolation layer with the surface of the substrate.

6. The device according to claim 1, wherein
an impurity concentration in the diffusion layer is in a range of 1.0×10¹² [cm⁻²] to 1.0×10¹³ [cm⁻²].

7. The device according to claim 1, wherein
the memory cell is included in one of first strings extending in a direction parallel to the first and second isolation layers, and
each of the first strings includes a plurality of memory cells arranged along the direction parallel to the first and second isolation layers, and two select transistors disposed on the well so as to sandwich the plurality of memory cells.

8. The device according to claim 7, wherein
the dummy cell is included in one of second strings extending in a direction parallel to the first and second isolation layers, and
each of the second strings includes a plurality of dummy cells arranged along the direction parallel to the first and second isolation layers, and two dummy select transistors disposed on the well so as to sandwich the plurality of dummy cells.

9. The device according to claim 8, wherein
the diffusion layer is formed to extend over the plurality of dummy cells in a second string in the direction perpendicular to the first and second isolation layers, and is separated between the second strings adjacent in the direction parallel to the first and second isolation layers.

10. The device according to claim 1, further comprising a depression-type peripheral transistor formed on the well,
the peripheral transistor including:
a gate insulator and a gate electrode sequentially disposed on the well;
a channel diffusion layer of the second conductivity type formed in the well under the gate electrode; and
source and drain diffusion layers of the second conductivity type formed in the well so as to sandwich the gate electrode,
wherein an impurity in the diffusion layer formed under the dummy cell is of the same kind as an impurity in the channel diffusion layer.

11. A method of manufacturing a nonvolatile semiconductor memory device, the method comprising:
forming a well of a first conductivity type in a substrate;
forming a diffusion layer of a second conductivity type in the well;
forming a first insulating layer and a first electrode layer on the well;
forming a plurality of first isolation layers penetrating the first electrode layer and the first insulating layer in a side portion of the diffusion layer, the first isolation layers being formed in parallel to each other to have bottom surfaces formed at positions lower than an upper face of the diffusion layer;
forming a second isolation layer penetrating the first electrode layer and the first insulating layer, the second isolation layer being formed in parallel to the first isolation layers at a position where the diffusion layer is sandwiched between the second isolation layer and the first isolation layers, a width of a substrate surface between the second isolation layer and the first isolation layers being set greater than a width of a substrate surface between the first isolation layers;
forming a second insulating layer and a second electrode layer on the first electrode layer and the first and second isolation layers;
processing a memory cell on the well between the first isolation layers, the memory cell including the first insulating layer, the first electrode layer, the second insulating layer, and the second electrode layer in sequence; and
processing a dummy cell on the well between the second isolation layer and the first isolation layers, the dummy cell including the first insulating layer, the first electrode layer, the second insulating layer, and the second electrode layer in sequence.

12. The method according to claim 11, wherein
the memory cell is formed so as to be included in one of first strings extending in a direction parallel to the first and second isolation layers, and
each of the first strings is formed so as to include a plurality of memory cells arranged along the direction parallel to the first and second isolation layers, and two select transistors formed on the well to sandwich the plurality of memory cells.

13. The method according to claim 12, wherein
the dummy cell is formed so as to be included in one of second strings extending in parallel to the first and second isolation layers, and
each of the second strings is formed so as to include a plurality of dummy cells arranged along the direction parallel to the first and second isolation layers, and two dummy select transistors formed on the well to sandwich the plurality of dummy cells.

14. The method according to claim 13, wherein
the diffusion layer is formed to extend over the plurality of dummy cells in a second string, and to be separated between the second strings adjacent in the direction parallel to the first and second isolation layers.

15. The method according to claim 14, wherein
the diffusion layer is formed by implanting an impurity of the second conductivity type into the well in a region where the second string is to be formed.

16. The method according to claim 14, wherein
the diffusion layer is formed by implanting an impurity of the second conductivity type into the well extending over regions where the second strings are to be formed, and then implanting an impurity of the first conductivity type into the well between the regions where the second strings are to be formed.

17. The method according to claim 11, wherein
the diffusion layer is formed by implanting an impurity of the second conductivity type into the well between a region where the second isolation layer is to be formed and regions where the first isolation layers are to be formed, and into the well in the region where the second isolation layer is to be formed, continuously.

18. The method according to claim 11, further comprising:
forming a channel diffusion layer of the second conductivity type in the well at the same time as forming the well;
forming, on the channel diffusion layer, a gate insulator and a gate electrode for a depression-type peripheral transistor; and
forming source and drain diffusion layers of the second conductivity type in the well so as to sandwich the gate electrode,
wherein an impurity in the diffusion layer formed under the dummy cell is of the same type as an impurity in the channel diffusion layer.
